(19) United States
(12) Patent Application Publication
(10) Pub. No.: US 2004/0062195 A1
(43) Pub. Date: Apr. 1, 2004

(54) Algorithm for dynamic provisioning of fail-over support in generalized multi-protocol label switching enabled networks

(75) Inventors: Manav Mishra, Hillsboro, OR (US); Huai-An Lin, Portland, OR (US); Harini Krishnamurthy, Baltimore, MD (US)

Correspondence Address: Pillsbury Winthrop LLP, Intellectual Property Group, 725 South Figueroa Street, Suite 2800, Los Angeles, CA, 90017-5406, US

(73) Assignee: Intel Corporation, Santa Clara, CA (US)

(21) Appl. No.: 10/261,669

(22) Filed: Sep. 30, 2002

(51) Int. Cl. G01R 31/08

(52) U.S. Cl. 370/217; 370/222

(57) ABSTRACT

An algorithm for dynamic provisioning of fail-over support in Generalized Multi-Protocol Label Switching (“GMPLS”) enabled networks is disclosed. A Fault-Tolerant Routing and Wavelength Assignment (“FT-RWA”) scheme uses a pseudo-dynamic mechanism to provide such fail-over support for the GMPLS networks. The FT-RWA scheme is capable of recovering from channel and link failures within the GMPLS network. When a channel failure occurs, some wavelength channels on the link fail. As a result, traffic on the affected light paths are switched to any unused and reserved wavelengths on the same link. If no wavelengths are available, the failure is perceived as a link failure. When a link failure occurs, all or part of the traffic is redirected to a neighboring node, designated as a “redirector”. The redirector node calculates alternate routes to the destination of that link and creates a light path on a suitable route when a failure occurs.

### BACKGROUND

1. Technical Field

Embodiments described herein are directed to dynamic provisioning of fail-over support in Generalized Multi-Protocol Label Switching (“GMPLS”) enabled networks. Specifically, an algorithm for a routing and wavelength assignment scheme takes into account the possibility of failure in the optical Wavelength Division Multiplexing (“WDM”) network and enables fast and efficient fail-over support.

2. Related Art

As GMPLS based networks become more widely deployed, fail-over support in these networks remain a persistent problem to be tackled. Schemes proposed in the past have been based primarily on static provisioning or over-provisioning of light paths to provide fail-over support for critical links/paths. Less discussed are the dynamic provisioning methods, which require more time for service restoration. Truly dynamic re-provisioning mechanisms require buffering of packets in the core and thus loss of connectivity until new paths are dynamically recomputed.

A Fault-Tolerant Routing and Wavelength Assignment (“FT-RWA”) scheme, as proposed in this disclosure, uses a pseudo-dynamic mechanism to provide fail-over support for GMPLS based networks. The FT-RWA scheme is defined within the framework of GMPLS and requires no changes to the GMPLS protocols. A pseudo-dynamic mechanism is more cost-effective than a static scheme, since static fail-over support, through over-provisioning, results in bandwidth waste. That is, the FT-RWA scheme provides the advantage of fast fail-over capability of static mechanisms while enjoying the low requirement for reserved wavelengths, representative of dynamic re-provisioning methods.

### BRIEF DESCRIPTION OF THE DRAWINGS

A detailed description of embodiments of the invention will be made with reference to the accompanying drawings, wherein like numerals designate corresponding parts in the several figures.

FIG. 1 is a diagram of a redirector node for traffic on a failed link in an optical wavelength division multiplexing (“WDM”) network according to an embodiment of the present invention.

FIG. 2 is a diagram of a redirector that calculates alternate routes for traffic according to an embodiment of the present invention.

FIG. 3 is an illustration of a mesh network according to an embodiment of the present invention.

FIG. 4 is an illustration of a chosen redirector node for a specified link according to an embodiment of the present invention.

FIG. 5 is an illustration of a redirector that calculates a route after removal of a node according to an embodiment of the present invention.

FIG. 6 is a flowchart for the network initialization stage of a fault-tolerant routing and wavelength assignment scheme according to an embodiment of the present invention.

FIG. 7 is a flowchart for the network operation phase of the fault-tolerant routing and wavelength assignment scheme according to an embodiment of the present invention.

FIG. 8A and FIG. 8B are flowcharts for execution by a source node of a failed link according to an embodiment of the present invention.

### DETAILED DESCRIPTION

The following paragraphs describe an algorithm for dynamic provisioning of fail-over support in Generalized Multi-Protocol Label Switching (“GMPLS”) enabled networks. That is, an algorithm for a routing and wavelength assignment scheme that takes into account the possibility of failure in the optical Wavelength Division Multiplexing (“WDM”) network and enables fast and efficient fail-over support is disclosed. WDM is a type of multiplexing developed for use on optical fiber. WDM modulates each of several data streams onto a different part of the light spectrum.

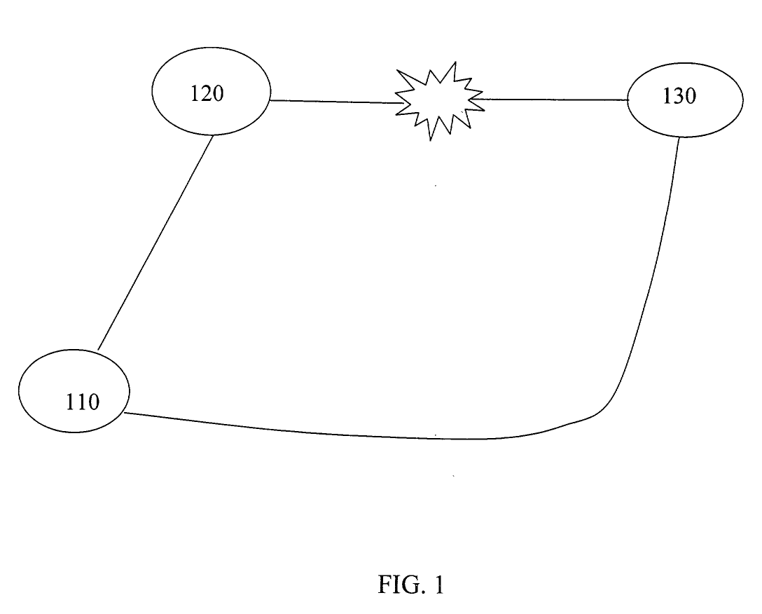

A Fault-Tolerant Routing and Wavelength Assignment (“FT-RWA”) scheme is capable of recovering from channel and link failures within the GMPLS network. When a channel failure occurs, some of the wavelength channels on the link fail. As a result, traffic on the affected light paths are switched to any unused and reserved wavelengths on the same link. If no wavelengths are available on the same link, the failure is perceived as a link failure. When a link failure occurs, all or part of the traffic is redirected to a neighboring node, which is designated as a “redirector” node 110, as shown in FIG. 1. The redirector node 110 calculates alternate routes to the destination of that link and creates a light path on a suitable route when a failure occurs. As depicted in FIG. 1, link 120-130 is a failed link, and the redirector node 110 operates as the redirector for traffic on the failed link 120-130.

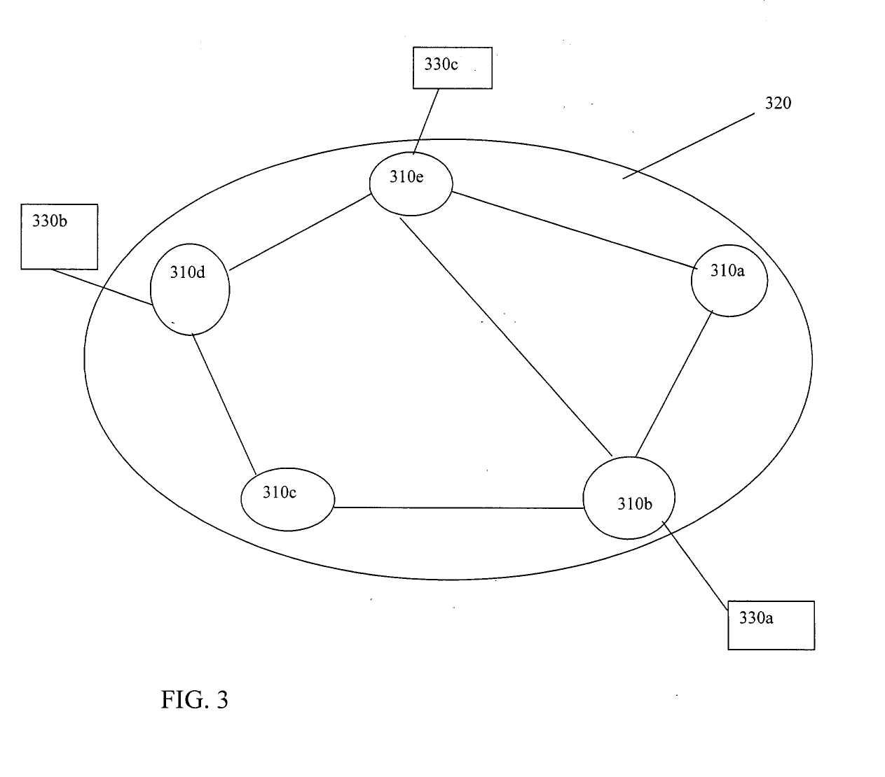

The main components of a GMPLS enabled network are optical cross-connects (“OXCs”) 310a-e, as shown in FIG. 3. The OXCs 310a-e support wavelength conversion and are capable of buffering traffic that passes through them for a brief period of time. The buffering may be achieved either through fiber delay loops or by means of optical-to-electronic conversion. The OXCs 310a-e are of two varieties—ordinary nodes and redirector nodes. The redirector nodes are the nodes that actively participate in the fault-recovery process. All of the OXCs 310a-e are Internet Protocol (“IP”) addressable.

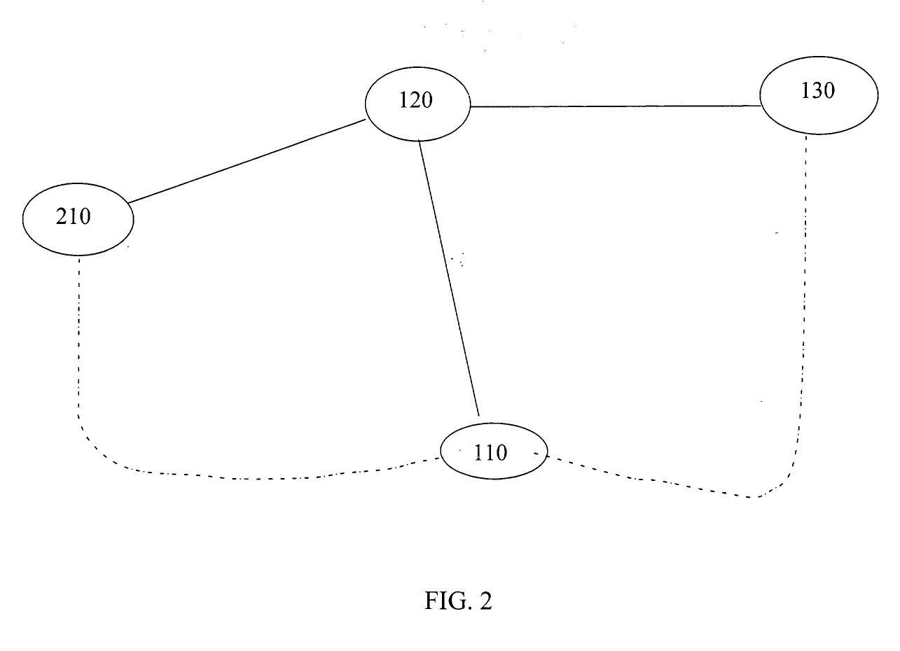

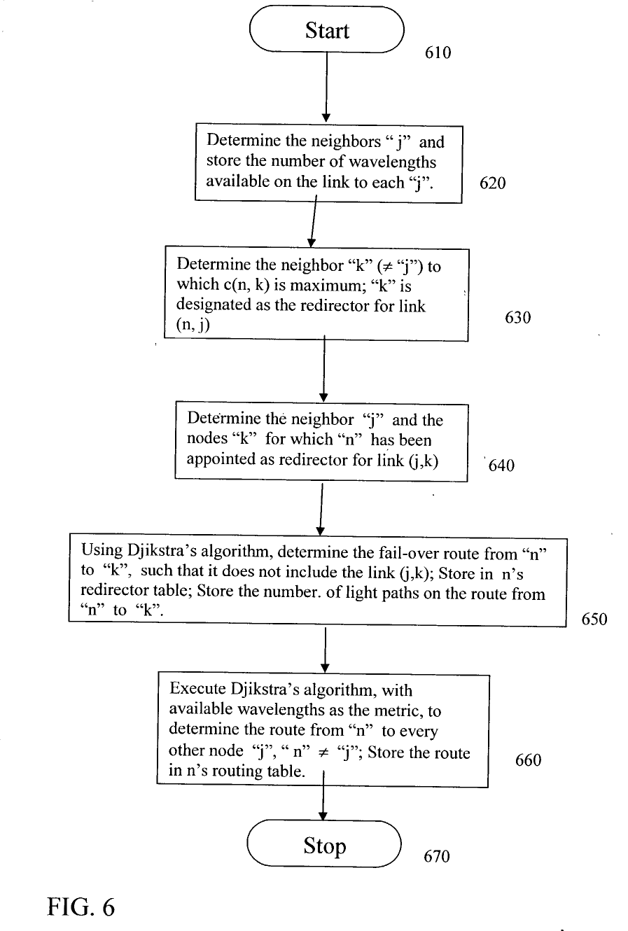

All OXCs 310a-e are ordinary nodes, having decoupled control planes and forwarding planes. Control planes perform signaling and routing. Forwarding planes forward data to the next hop on the light path. A GMPLS control plane is assumed. Redirector nodes are ordinary nodes with the added responsibility of determining alternate routes for fault recovery. During network initialization, explained in detail in FIG. 6, every node “n” in the network chooses a set of redirectors, based on certain criteria, for connections on the links to neighboring nodes. The redirector node is a neighbor of node “n” other than the destination of the link that has the maximum number of wavelengths on it. Redirector nodes are allocated a set of destinations (neighbors of “n”), for which they have to calculate alternate routes, which do not include the link between “n” and the neighbor. This is illustrated in FIG. 2, where the redirector node 110 is appointed by node 120 as redirector for traffic on the links 120-130 and 120-210. The redirector node 110 calculates alternate routes to 130 and 210, without including the links 120130 and 120-210. The dashed lines represent the calculated alternate routes.

Fiber optic links connect the OXCs 310a-e in the network. Because of the deployment of WDM technology, data streams that belong to different connections may be transmitted on a single fiber link. A possible measure of the link cost is the number of wavelengths that are available for use on the link. This variable changes as light paths traversing the link are created and deleted. Of the total number of wavelengths available on a link, a certain number of wavelengths are reserved for purposes of restoration. The motivation behind the reservation of wavelengths is four-pronged, namely in decreasing order of priority: a) to achieve restoration in the event of failure; (b) to achieve congestion control; (c) to serve as additional signaling channels; and (d) to carry low-priority traffic. That is, if there is failure and congestion in the network, the reserved wavelengths will be used first to recover from failure, and should any reserved wavelengths remain, to control congestion second.

As shown in FIG. 3, the network under consideration is a wavelength-routed mesh network. A wavelength-routed mesh network is a network whose OXCs 310a-e route and switch optical signals based on their wavelengths. A mesh network is a general network that does not have any specific characteristics. The OXCs 310a-e are capable of wavelength conversion. The mesh network forms the core network 320 through which higher layer nodes, for example, 330a-c communicate.

As previously stated, the proposed FT-RWA scheme operates in GMPLS networks. As such, GMPLS protocols are required for signaling, routing, and management. A primary purpose of the signaling protocol is the creation and deletion of light paths. The routing protocol used is the Open Shortest Path First (“OSPF”) protocol. OSPF is a link state routing protocol. Neighboring nodes exchange information by means of Link Summary Advertisements (“LSAs”), which are used to update the link state database at each node. OSPF uses Dijkstra's shortest path algorithm to build a routing table. Dijkstra's algorithm is executed at every node to find the route from itself to every other node in the network. To find appropriate routes for optical WDM networks, wavelength information is taken into account while executing Dijkstra's algorithm. For example, the cost associated with each link can be the number of available wavelengths on the link. Dijkstra's algorithm provides an efficient mechanism for solving the shortest-path problem. For example, weights attached to the edges of a network can be used to represent quantities such as distances, costs, or times. In general, if it is desired to find the minimum distance from one given node of a network, called the source node or start node, to all the nodes of the network, Dijkstra's algorithm uses the distance along a path as the sum of the weights of that path to calculate the minimum of the distance of any path from node the source node to another node in the network.

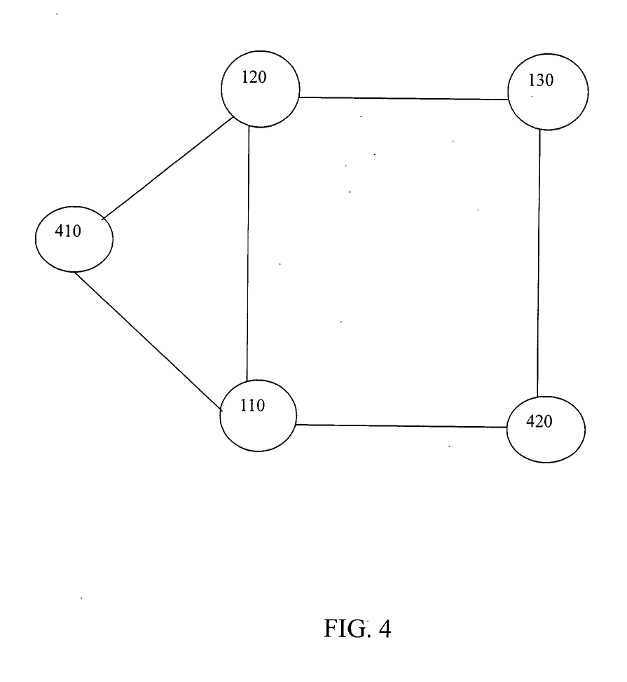

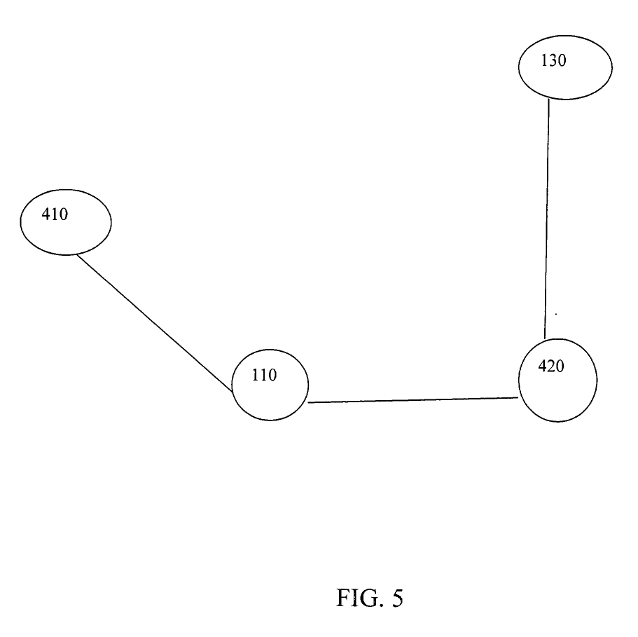

In the FT-RWA scheme, the routing algorithm executed at the redirector node 110 incorporates some constraints in order to calculate the alternate routes to the destinations. The route must not include the link for which the node has been appointed as the redirector 110. For example, as previously discussed with respect to FIG. 2, the redirector node 110 is appointed by node 120 as the redirector for link 120-130. The route that redirector node 110 calculates to node 130 must not include the link 120-130. To achieve this, a constraint-based routing algorithm, the Constraint-based Shortest Path First (“CSPF”), is executed by the redirector node 110. CSPF is a variation of OSPF in that the constraint of excluding a particular link from the route is imposed. As illustrated in FIG. 4 and FIG. 5, to achieve this, the redirector node 110 runs Dijkstra's algorithm on a graph from which the node that appointed it as redirector has been removed. That is, like FIG. 2, in FIG. 4, redirector node 110 is chosen as redirector for link 120-130. Nodes 410 and 420 are not chosen as redirectors. In FIG. 5, node 120 is removed from the graph and redirector node 110 calculates the route to node 130. Nodes 410 and 420 need not be removed from the graph.

A management protocol is required to maintain control channel connectivity and detect and isolate faults. The management protocol that is used at the nodes may be, for example, the Link Management Protocol (“LMP”). Three types of information maintained by the nodes of the network include the following: (a) neighbor information; (b) redirector information; and (c) routing information. Regarding neighbor information, each node stores information on its neighbors, including the number of free and reserved wavelengths to the neighbor and the redirector node assigned for the link to that neighbor. Concerning redirector information, every redirector node maintains information on links for which it is serving as redirector, including the number of light paths available to that destination and the route to that destination. The route is calculated by using the CSPF algorithm. With respect to routing information, every node stores the route to every other node in the network. This route is calculated using Dijkstra's algorithm, with the available wavelengths as the cost associated with each link. State information is updated every time that a change occurs in the network.

The two main phases in which the network exists are the network initialization phase and the network operation phase. A flowchart for the network initialization phase to be executed at every node, “n”, in the network is provided in FIG. 6. Initialization commences at operation 610. Operations 620 and 630 together constitute neighbor discovery. As depicted by operation 620, neighbor nodes “j” are determined, and the number of wavelengths available on the link to each “j” are stored. Next, in operation 630, neighbor nodes “k” are determined, where “k” does not equal “j”, based on some criterion. For instance, to which c(n, k) maximum, k is the redirector for link (n, j) and c(n, k) is the number of available wavelengths at a node.

Operations 640 and 650 together constitute redirector initialization. In operation 640, neighbors “j” and the nodes “k” for which “n” has been appointed as redirector for link (j, k) are determined. Next, in operation 650, the route from “n” to “k” is determined using Dijkstra's algorithm so that it does not include the link (j, k). The route is stored in n's redirector table, and the number of light paths on the route from “n” to “k” is also stored.

Operation 660 constitutes routing information initialization. In operation 660, Dijkstra's algorithm is executed with available wavelengths to determine the route from “n” to every other node “j”, where “n” does not equal “j.” The route is stored in n's routing table. Network initialization is completed at operation 670.

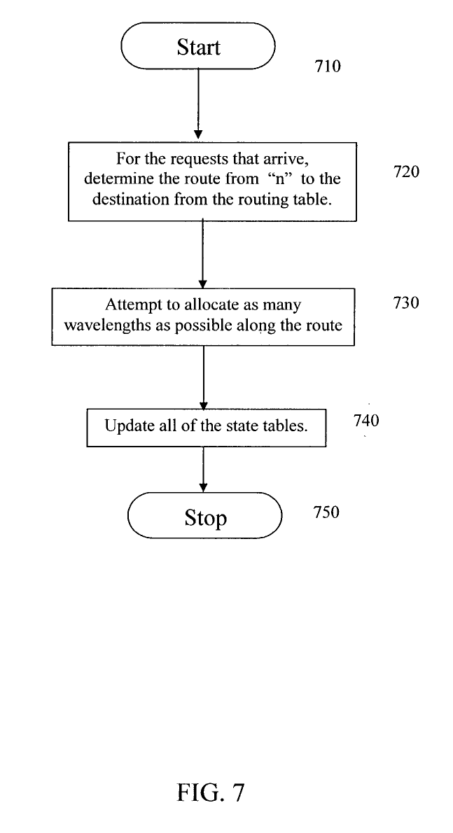

A flowchart for the network operation phase to be executed at every node, “n”, in the network is provided in FIG. 7. Network operation commences at operation 710. As depicted in operation 720, for the requests that arrive, the route from “n” to the destination is determined from the routing table. An allocation of as many wavelengths as possible along the route is attempted in operation 730. Then, in operation 740, all state tables are updated. Network operation is completed at operation 750.

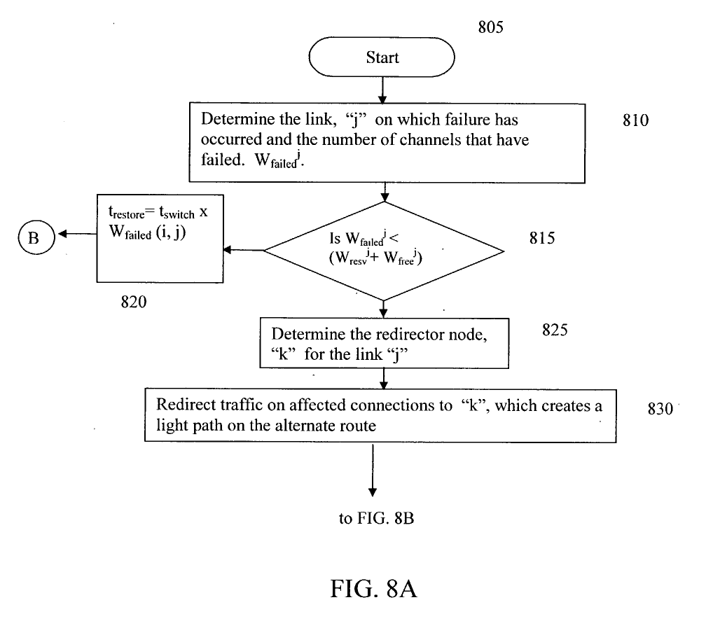

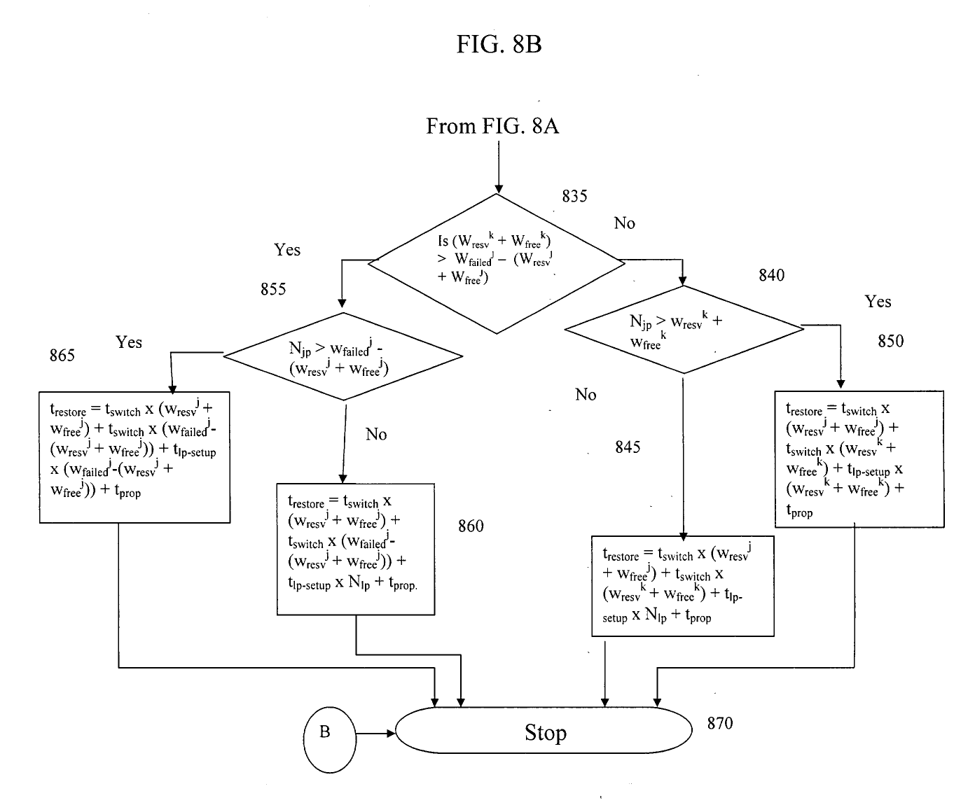

In the event of failure, a flowchart of the operations to be executed by a source node of the failed link is provided in FIGS. 8A-8B. The operation commences at operation 805. In operation 810, the link “j” on which failure has occurred and the number of channels that have failed, w_{failed}^{j}, are determined. Next, in operation 815, it is determined whether w_{failed}^{j}<(wᵣₑₛᵥ^{j}+w_{free}^{j}). If yes, restoration is calculated by tᵣₑₛₜₒᵣₑ=t_{switch}×w_{failed} (i, j), as shown in operation 820.

Otherwise, operation 825 determines the redirector node “k” for the link “j”. As such, traffic on affected connections to “k” is redirected, which creates a light path on the alternate route, as shown in operation 830. In operation 835, it must be determined whether (wᵣₑₛᵥ^{k}+w_{free}^{k})>w_{failed}^{j}−(wᵣₑₛᵥ^{j}+w_{free}^{j}). If no, as shown in operation 840, it must then be determined whether Nⱼₚ>wᵣₑₛᵥ^{k}+w_{free}^{k}. If no, as shown in operation 845, restoration is calculated by tᵣₑₛₜₒᵣₑ=t_{switch}×(wᵣₑₛᵥ^{j}+w_{free}^{j})+t_{switch}×(wᵣₑₛᵥ^{k}+w_{free}^{k})+tₗₚ₋ₛₑₜᵤₚ×Nₗₚ+tₚᵣₒₚ. If Nⱼₚ>wᵣₑₛᵥ^{k}+w_{free}^{k}, then as shown in operation 850, restoration is calculated by tᵣₑₛₜₒᵣₑ=t_{switch}×(wᵣₑₛᵥ^{j}+w_{free}^{j})+t_{switch}×(wᵣₑₛᵥ^{k}+w_{free}^{k})+tₗₚ₋ₛₑₜᵤₚ×(wᵣₑₛᵥ^{k}+w_{free}^{k})+tₚᵣₒₚ

If (wᵣₑₛᵥ^{k}+w_{free}^{k})>w_{failed}^{j}−(wᵣₑₛᵥ^{j}+w_{free}^{k}), then as shown by operation 855, it must be determined whether Nⱼₚ>w_{failed}^{j}−(wᵣₑₛᵥ^{j}+w_{free}^{j}). If no, then as illustrated in operation 860, restoration is calculated by tᵣₑₛₜₒᵣₑ=t_{switch}×(wᵣₑₛᵥ^{j}+w_{free}^{j})+t_{switch}×(w_{failed}^{j}−(wᵣₑₛᵥ^{j}+w_{free}^{j}))+tₗₚ₋ₛₑₜᵤₚ×Nₗₚ+tₚᵣₒₚ, If yes, then as depicted in operation 865, restoration is calculated by tᵣₑₛₜₒᵣₑ=t_{switch}×(wᵣₑₛᵥ^{j}+w_{free}^{j})+t_{switch}×(w_{failed}^{j}−(wᵣₑₛᵥ^{j}+w_{free}^{j}))+tₗₚ₋ₛₑₜᵤₚ×(w_{failed}^{j}−(wᵣₑₛᵥ^{j}+w_{free}^{j}))+tₚᵣₒₚ. The total operation ends at operation 870.

While the above description refers to particular embodiments of the present invention, it will be understood to those of ordinary skill in the art that modifications may be made without departing from the spirit thereof. The accompanying claims are intended to cover any such modifications as would fall within the true scope and spirit of the embodiments of the present invention. The presently disclosed embodiments are therefore to be considered in all respects as illustrative and not restrictive; the scope of the embodiments of the invention being indicated by the appended claims, rather than the foregoing description. All changes that come within the meaning and range of equivalency of the claims are therefore intended to be embraced therein.

What is claimed is:

1. A Generalized Multi-Protocol Label Switching (“GMPLS”) enabled network, comprising:
a plurality of optical cross-connects, connected by fiber optic links, operating as at least one of ordinary nodes and redirector nodes, to route and switch optical signals based on wavelength;
a core network, housing the optical cross-connects; and
a plurality of higher layer nodes, which communicate through the core network.

2. The Generalized Multi-Protocol Label Switching enabled network of claim 1, wherein the plurality of optical cross-connects buffer traffic through at least one of fiber delay loops and optical-to-electronic conversion.

3. The Generalized Multi-Protocol Label Switching enabled network of claim 2, wherein the plurality of optical cross-connects are Internet Protocol (“IP”) addressable.

4. The Generalized Multi-Protocol Label Switching enabled network of claim 1, wherein the ordinary nodes have decoupled control planes to perform signaling and routing, and forwarding planes to forward data to a next hop on a light path.

5. The Generalized Multi-Protocol Label Switching enabled network of claim 4, wherein the redirector nodes are ordinary nodes that calculate alternate routes for fault recovery.

6. The Generalized Multi-Protocol Label Switching enabled network of claim 1, wherein during network initialization, all nodes in the network choose a set of redirector nodes for connections on links to neighboring nodes.

7. The Generalized Multi-Protocol Label Switching enabled network of claim 6, wherein redirector nodes are allocated a set of destinations for which the redirector nodes calculate alternate routes.

8. The Generalized Multi-Protocol Label Switching enabled network of claim 7, wherein the alternate routes calculated by the redirector nodes do not include a link between a node and a neighbor.

9. The Generalized Multi-Protocol Label Switching enabled network of claim 5, wherein the redirector nodes create a light path on a suitable route when a failure occurs.

10. A method of network initialization, comprising:
determining neighboring nodes “j” and storing available wavelengths on a link to the neighboring nodes;
determining neighboring nodes “k”;
determining the neighboring nodes “j” and the neighboring nodes “k” for which “n” is appointed as redirector;
determining a route from “n” to “k” using an algorithm so that link (j,k) is not included;
storing the route in n's redirector table;
storing light paths on the route from “n” to “k”;
executing the algorithm with available wavelengths to determine the route from “n” to every other node “j”; and
storing the route in n's routing table.

11. The method of network initialization of claim 10, wherein “k” does not equal “j”.

12. The method of network initialization of claim 10, wherein the algorithm used is Dijkstra's algorithm with the available wavelengths associated with each link;

13. The method of network initialization of claim 10, wherein “n” does not equal “j”.

14. A method of network operation, comprising:
determining, from a routing table, a route from node “n” to a destination;
allocating at least one of a plurality of wavelengths along the determined route; and
updating all state tables.

15. The method of network operation of claim 14, wherein the route from “n” to the destination is determined for arriving requests.

16. A method to be executed by a source node of a failed link, comprising:
determining a link “j” on which failure has occurred and determining a number of channels that have failed;
determining whether the number of channels that have failed is less than a sum of a number of reserved “j” channels and free “j” channels;
calculating restoration;
determining a redirector node “k” for the link “j”;
redirecting traffic on affected connections to redirector node “k”;
determining whether the sum of reserved channels and free channels for redirector node “k” is greater than the number of “j” channels that have failed minus the sum of the number of reserved “j” channels and free “j” channels; and
computing further restoration values based on the determinations.

17. The method to be executed by the source node of the failed link of claim 16, wherein redirection of traffic on affected connections to redirector node “k” creates a light path on an alternate route.

18. An article, comprising:
a storage medium having stored thereon instructions that when executed by a machine result in the following:
determining a link “j” on which failure has occurred and determining a number of channels that have failed on the link;
determining whether the number of channels that have failed is less than a sum of a number of reserved “j” channels and free “j” channels;
computing restoration;
determining a redirector node “k” for the link “j”;
redirecting traffic on affected connections to redirector node “k”;
determining whether the sum of reserved channels and free channels for redirector node “k” is greater than the number of “j” channels that have failed minus the sum of the number of reserved “j” channels and free “j” channels; and
calculating further restoration values.

19. The article of claim 18, wherein redirection of traffic on affected connections to redirector node “k” creates a light path on an alternate route.

20. An article, comprising:
a storage medium having stored thereon instructions that when executed by a machine result in the following:
determining neighboring nodes “j” and storing available wavelengths on a link to the neighboring nodes;
determining neighboring nodes “k”;
determining neighboring nodes “j” and the neighboring nodes “k” for which “n” is appointed as redirector;
determining a route from “n” to “k” using an algorithm so that (j,k) is not included;
storing the route in n's redirector table;
storing light paths on the route from “n” to “k”;
executing the algorithm with available wavelengths to determine the route from “n” to every other node “j”; and
storing the route in n's routing table.

21. The article of claim 20, wherein “k” does not equal “j”.

22. An article comprising:
a storage medium having stored thereon instructions that when executed by a machine result in the following:
determining a route from node “n” to a destination;
allocating at least one of a plurality of wavelengths along the determined route, and
updating all state tables.

23. The article of claim 22, wherein the route from “n” to the destination is determined for arriving requests.

24. The article of claim 22, wherein the route from node “n” to the destination is determined from a routing table.
